(19) United States
(12) Patent Application Publication
(10) Pub. No.: US 2024/0352615 A1
(43) Pub. Date: Oct. 24, 2024

(54) Method, Apparatus, Equipment for Accurately Adjusting ADC Camera and Computer Storage Medium

(71) Applicant: XI’AN ESWIN MATERIAL TECHNOLOGY CO., LTD., Xi'an (CN)

(72) Inventors: Shaojie SONG, Xi'an (CN); Zhenliang SONG, Xi'an (CN)

(21) Appl. No.: 18/569,189

(22) PCT Filed: Sep. 22, 2022
(86) PCT No.: PCT/CN2022/120556

§ 371 Date: Dec. 11, 2023

(30) Foreign Application Priority Data
Sep. 24, 2021 (CN) 202111124306.4

(51) Int. Cl. C30B 15/26; C30B 29/06

(52) U.S. Cl. CPC C30B 15/26; C30B 29/06

(57) ABSTRACT

A method for accurately adjusting an automatic diameter control (ADC) camera includes before pulling a monocrystalline silicon ingot, obtaining a height variation value of an ADC camera from a solid-liquid interface of a melt by separately comparing variations of thermal field accessories provided corresponding to the monocrystalline silicon ingot and a previous monocrystalline silicon ingot. Based on a geometric relationship between the height variation value and a horizontal displacement of the ADC camera, a horizontal displacement of the ADC camera is obtained according to the height variation value, wherein the horizontal displacement is a first horizontal displacement or a second horizontal displacement. The method also includes moving the ADC camera horizontally to a target position according to the horizontal displacement of the ADC camera.

### CROSS-REFERENCE TO RELATED APPLICATION

The present application is a U.S. national phase of the PCT Application No. PCT/CN2022/120556 filed on Sep. 22, 2022, which claims a priority to the Chinese patent application No. 202111124306.4 filed in China on Sep. 24, 2021, disclosures of which are incorporated herein by reference in their entireties.

### TECHNICAL FIELD

Embodiments of the present disclosure relate to the field of semiconductor technologies, in particular to a method, apparatus and equipment for accurately adjusting an ADC camera and a computer storage medium.

### BACKGROUND

Electronic-grade monocrystalline silicon ingots, as a semiconductor material, are generally used for manufacturing integrated circuits and other electronic components. At present, a common method for growing monocrystalline silicon ingots is the Czochralski method, also known as the CZ method. The method involves dipping a seed crystal into a silicon melt placed in a crucible in a monocrystalline puller; pulling the seed crystal while rotating the seed crystal and the crucible to sequentially perform process operations at the end of the seed such as dip process, shoulder process, over-shoulder process, body process and tail process, thereby obtaining a monocrystalline silicon ingot. At present, in order to obtain electronic-grade wafers that meet different application purposes, technicians need to use different thermal fields and process conditions to prepare different monocrystalline silicon ingots.

### SUMMARY

In a first aspect, one embodiment of the present disclosure provides a method for accurately adjusting an automatic diameter control (ADC) camera, comprising:
before pulling a monocrystalline silicon ingot, obtaining a height variation value of an ADC camera from a solid-liquid interface of a melt by separately comparing variations of thermal field accessories provided corresponding to the monocrystalline silicon ingot and the previous one;
based on a geometric relationship between the height variation value and a horizontal displacement of the ADC camera, obtaining the horizontal displacement of the ADC camera according to the height variation value; wherein the horizontal displacement is a first horizontal displacement or a second horizontal displacement; and
moving the ADC camera to a target position horizontally according to the horizontal displacement of the ADC camera.

In a second aspect, one embodiment of the present disclosure provides an apparatus for accurately adjusting an ADC camera, comprising: a first obtaining portion, a second obtaining portion and a moving portion;
wherein the first obtaining portion is configured to, before pulling a monocrystalline silicon ingot, obtain a height variation value of an ADC camera from a solid-liquid interface of a melt, by separately comparing variations of thermal field accessories provided corresponding to the monocrystalline silicon ingot and a previous monocrystalline silicon ingot;
the second obtaining portion is configured to, based on a geometric relationship between the height variation value and a horizontal displacement of the ADC camera, obtain the horizontal displacement of the ADC camera according to the height variation value; wherein the horizontal displacement is a first horizontal displacement or a second horizontal displacement;
the moving portion is configured to move the ADC camera to a target position horizontally according to the horizontal displacement of the ADC camera.

In a third aspect, one embodiment of the present disclosure provides an equipment for accurately adjusting an ADC camera, comprising: a communication interface, a memory and a processor, which are coupled together by a bus system;
wherein the communication interface is configured to receive and send signals during a process of receiving and sending information with other external network elements;
the memory is configured to store computer programs executed on the processor;
the processor is configured to execute the computer programs to perform the method described in the first aspect for accurately adjusting the ADC camera while executing the computer program.

In a fourth aspect, one embodiment of the present disclosure provides a computer storage medium, comprising programs for accurately adjusting an ADC camera stored therein; wherein the programs for accurately adjusting the ADC camera are executed by at least one processor to implement steps of the method described in the first aspect for accurately adjusting the ADC camera.

In a fifth aspect, one embodiment of the present disclosure provides a computer program product stored in a non-volatile storage medium, wherein the computer program product, when executed by at least one processor, implements the steps of the method described in the first aspect for accurately adjusting the ADC camera.

### BRIEF DESCRIPTION OF THE DRAWINGS

FIG. 1 is a structural schematic diagram of a monocrystalline puller according to an embodiment of the present disclosure;

FIG. 2 is a schematic diagram showing position variations of a thermal field accessory in a monocrystalline puller according to an embodiment of the present disclosure;

FIG. 3 is a schematic flowchart of a method for accurately adjusting an ADC camera according to an embodiment of the present disclosure;

FIG. 4 is a schematic diagram showing a geometric relationship between a height variation value of an ADC camera from a solid-liquid interface of the melt and a horizontal displacement of the ADC camera according to an embodiment of the present disclosure;

FIG. 5 is a schematic diagram showing an rotation angle Δ θ of an ADC camera according to an embodiment of the present disclosure;

FIG. 6 is a schematic diagram showing a horizontal movement of an ADC camera to a target position according to an embodiment of the present disclosure;

FIG. 7 is a schematic diagram of an apparatus for accurately adjusting an ADC camera according to an embodiment of the present disclosure; and

FIG. 8 is a schematic diagram showing hardware structures of an equipment for accurately adjusting an ADC camera according to an embodiment of the present disclosure.

### DETAILED DESCRIPTION

The technical solutions in the embodiments of the present disclosure will be described clearly and completely hereinafter in conjunction with the accompanying drawings in the embodiments of the present disclosure.

In a common method for growing monocrystalline silicon ingots, the body process phase is an extremely important process in growing process and a key to ensure the quality of the monocrystalline silicon ingot. It is necessary to quickly and effectively achieve a required growth diameter of the monocrystalline silicon ingot in an initial stage of the body process phase. However, due to different needs of the monocrystalline silicon ingots, it is usually necessary to make certain adjustments to thermal field accessories of the monocrystalline puller. Due to the fact that the adjustments of the thermal field accessories are to ensure the growth diameter of the monocrystalline silicon ingot, an automatic diameter control (ADC) camera also needs to be adjusted as the thermal field accessories are adjusted. In conventional technical solutions, a position to be adjusted of the ADC camera is usually obtained by an actual scale measurement when the monocrystalline silicon ingot is about to enter or has already entered the body process phase. In this case, the adjustment of the ADC camera has a certain degree of delay, and repeated adjustments are required to adjust the ADC camera to a target position to monitor the growth diameter of the monocrystalline silicon ingot.

In view of this, embodiments of the present disclosure aim to provide a method, apparatus and equipment for accurately adjusting an ADC camera and a computer storage medium, which can accurately and timely determine a target position of the ADC camera after adjustments of the thermal field accessories, so that growth of the monocrystalline silicon ingot quickly and stably enters the body process phase from an initial stage of the body process phase, thereby improving quality of the monocrystalline silicon ingot in the initial stage of the body process phase.

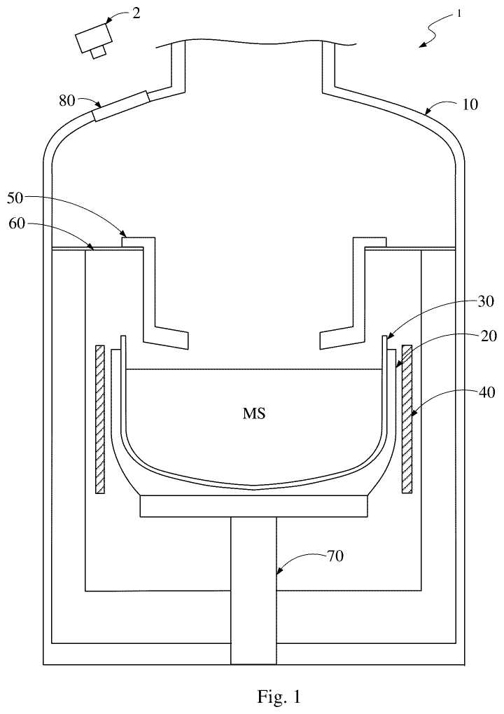

Referring to FIG. 1, it shows a monocrystalline puller 1 that can implement the technical solutions of the embodiments of the present disclosure. The monocrystalline puller 1 comprises a puller body 10, a heating apparatus and a pulling apparatus provided in the puller body 10. The heating apparatus comprise a graphite crucible 20, a quartz crucible 30, a heater 40, etc. The quartz crucible 30 is used to hold silicon raw materials, such as polycrystalline silicon. The silicon raw materials are heated and melted into a melt MS in the quartz crucible 30. The graphite crucible 20 is wrapped on an outer side of the quartz crucible 30 to provide support for the quartz crucible 30 during heating process. The heater 40 is provided at an outer side of the graphite crucible 20. A thermal shield 50 is provided above the quartz crucible 30. The thermal shield 50 is suspended on a thermal insulation cover plate 60, wherein the thermal shield 50 has an inverted conical shield-shaped portion, which extends downwards and around a growth area of the monocrystalline silicon ingot, and which can block direct thermal radiation from the heater 40 and the high-temperature melt MS to the grown monocrystalline silicon ingot, thereby reducing temperature of the monocrystalline silicon ingot. Meanwhile, the thermal shield 50 can also make downward-blown protective gas concentrated and directly sprayed near a growth interface, thereby further enhancing heat dissipation of the monocrystalline silicon ingot. A crucible shaft 70 is provided at a bottom of the graphite crucible 20. A crucible shaft driving apparatus (not shown) is provided at a bottom of the crucible shaft 70 to enable the crucible shaft 70 to drive the quartz crucible 30 to rotate.

It is to be noted that the structures of the monocrystalline puller 1 shown in FIG. 1 are not specifically limited, and other components required for implementing the Czochralski method for preparing monocrystalline silicon ingots are omitted in order to clearly illustrate the technical solutions of the embodiments of the present disclosure. Based on the monocrystalline puller 1 shown in FIG. 1, an observation window 80 may also be opened at an upper portion of the puller body 10 for an ADC camera 2 to monitor a growth diameter of the monocrystalline silicon ingot.

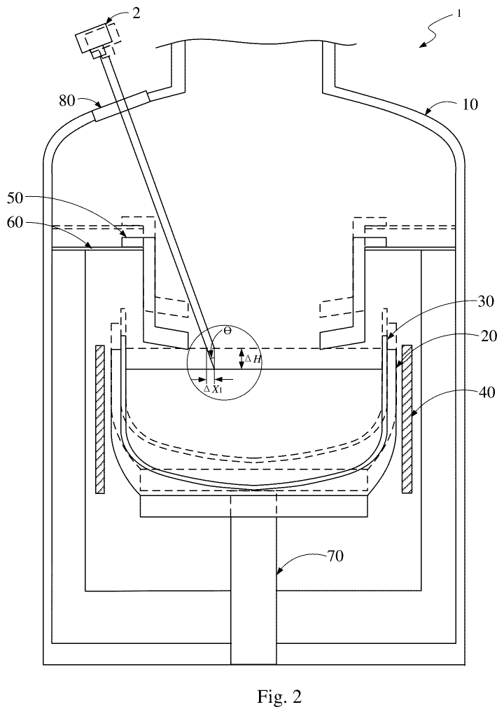

When using the above monocrystalline puller 1 for preparing the monocrystalline silicon ingot, it is necessary to adjust thermal field accessories for different requirements of the monocrystalline silicon ingots. For example, as shown in FIG. 2, when preparing a previous monocrystalline silicon ingot, the thermal field accessories in the monocrystalline puller 1 are at a position shown in solid lines; for a current monocrystalline silicon ingot with different requirements, the thermal field accessories in the monocrystalline puller 1 are at a position shown in dashed lines. It is to be understood that for the previous monocrystalline silicon ingot and the current monocrystalline silicon ingot, adjustments of the thermal field accessories in the monocrystalline puller 1 are to ensure consistent growth diameter of prepared monocrystalline silicon ingots on the basis of meeting different requirements. It is to be understood that after adjusting the thermal field accessories corresponding to the current monocrystalline silicon ingot, as shown in FIG. 2, a height position of a solid-liquid interface of the melt MS will also be varied, which means that a height of the ADC camera from the solid-liquid interface of the melt MS has been varied. Therefore, in order to ensure that the growth diameter of the current monocrystalline silicon ingot is consistent with the growth diameter of the previous monocrystalline silicon ingot, the position of the ADC camera 2 also needs to be adjusted. For example, in FIG. 2, the ADC camera 2 moves horizontally from a position shown with solid lines to a position shown with dashed lines. However, in conventional technical solutions, when the current monocrystalline silicon ingot is about to enter the body process phase or has already entered the body process phase, a movement displacement of the ADC camera 2 will be measured by an actual scale. It is to be understood that due to delay in the measurement of the actual scale and the need to repeatedly adjust the ADC camera 2 according to measurement data, it has an impact on control accuracy of the growth diameter of the monocrystalline silicon ingot.

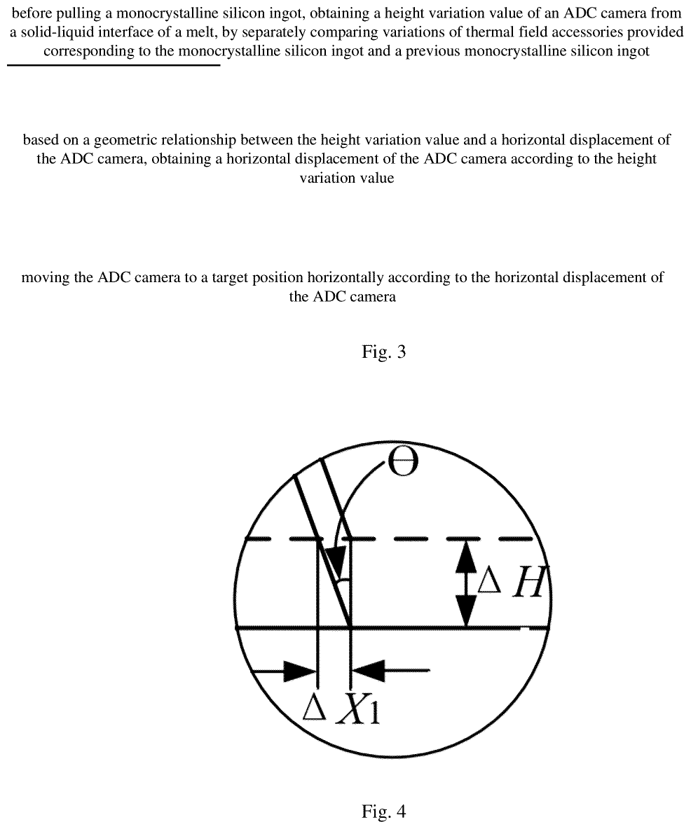

Therefore, based on the above explanation, referring to FIG. 3, FIG. 3 shows a method for accurately adjusting an ADC camera according to an embodiment of the present disclosure. The method specifically comprises:
S301: before pulling a monocrystalline silicon ingot, obtaining a height variation value of an ADC camera from a solid-liquid interface of a melt, by separately comparing variations of thermal field accessories provided corresponding to the monocrystalline silicon ingot and a previous monocrystalline silicon ingot;
S302: based on a geometric relationship between the height variation value and a horizontal displacement of the ADC camera, obtaining a horizontal displacement of the ADC camera according to the height variation value; where the horizontal displacement is a first horizontal displacement or a second horizontal displacement;
S303: moving the ADC camera to a target position horizontally according to the horizontal displacement of the ADC camera.

For the technical solutions shown in FIG. 3, before pulling the monocrystalline silicon ingot, the height variation value of the ADC camera from the solid-liquid interface of the melt is obtained, by comparing variations of the thermal field accessories provided corresponding to the monocrystalline silicon ingot and the previous monocrystalline silicon ingot. On this basis, based on the geometric relationship between the height variation value and the horizontal displacement of the ADC camera, and according to the height variation value, the horizontal displacement of the ADC camera is obtained. Finally, the ADC camera is moved horizontally to the target position, so that the target position of the ADC camera can be accurately and timely determined after adjustments of the thermal field accessories, which enables growth of the monocrystalline silicon ingot to quickly and stably enter the body process phase from an initial stage of the body process phase, thereby improving quality of the monocrystalline silicon ingot in the initial stage of the body process phase.

For the technical solutions shown in FIG. 3, in some examples, the variations of the thermal field accessories provided corresponding to the monocrystalline silicon ingot and the previous monocrystalline silicon ingot, comprise:
a height variation of a thermal insulation cover plate in the monocrystalline puller, a length variation of a thermal shield, and a melt gap variation of the melt between pulling the monocrystalline silicon ingot and the previous monocrystalline silicon ingot.

For the technical solutions shown in FIG. 3, in some examples, before pulling the monocrystalline silicon ingot, the obtaining a height variation value of an ADC camera from a solid-liquid interface of a melt, by separately comparing variations of thermal field accessories provided corresponding to the monocrystalline silicon ingot and the previous monocrystalline silicon ingot, comprises:
obtaining a height variation value Δh₁ of the thermal insulation cover plate, a length variation value Δh₂ of the thermal shield and a melt gap variation value Δh₃ of the melt respectively, by comparing the variations of the thermal field accessories provided corresponding to the monocrystalline silicon ingot and the previous monocrystalline silicon ingot;
when pulling the current monocrystalline silicon ingot, according to the height variation value Δh₁ of the thermal insulation cover plate, the length variation value Δh₂ of the thermal shield and the melt gap variation value Δh₃ of the melt, obtaining a height variation value ΔH=Δh₁+Δh₂+Δh₃ of the ADC camera from the solid-liquid interface of the melt.

It is to be understood that, as shown in FIG. 2, in the actual pulling process of the current monocrystalline silicon ingot, due to differences for product demands between the current monocrystalline silicon ingot and the previous monocrystalline silicon ingot, the thermal field accessories in the monocrystalline puller 1 also need to be adjusted accordingly. In this case, it will cause a variation in a height position of the solid-liquid interface of the melt MS, which will also cause the height of the ADC camera 2 from the solid-liquid interface of the melt to vary. Specifically, when a height of a supporting component varies, it will cause a variation Δh₁ of the position of the thermal insulation cover plate 60. It is to be understood that in the monocrystalline puller 1, as the height position of the thermal insulation cover plate 60 varies, the height position of the thermal shield 50 also varies with the variation of the thermal insulation cover plate 60. Therefore, the height variation value Δh₁ of the insulation cover plate 60 also represents a height variation value of the thermal shield 50. On the other hand, during the actual pulling process, for pulling different monocrystalline silicon ingots, in order to ensure the growth diameter of the monocrystalline silicon ingots, the length of the thermal shield 50 will also be adjusted. In the embodiments of the present disclosure, the length variation value of the thermal shield 50 is set as Δh₂. Meanwhile, during the adjustment process of the thermal field accessories, the melt gap of the melt will also varies. In the embodiments of the present disclosure, the variation value of the melt gap of the melt is set as Δh₃. Therefore, it is to be understood that before pulling the monocrystalline silicon ingot, the variation values of these thermal field accessories can be used to calculate the height variation value ΔH=Δh₁+Δh₂+Δh₃ of the ADC camera 2 from the solid-liquid interface of the melt MS. Of course, it is to be understood that in the actual pulling process, adjustments of other thermal field accessories in the monocrystalline puller 1, in addition to the above described thermal field accessories, will also affect the height of the solid-liquid interface of the melt MS, resulting in a variation in the height of the ADC camera 2 from the solid-liquid interface of the melt MS. Therefore, it is to be noted that in the implementation process of the embodiments of the present disclosure, the height variation value of the ADC camera 2 from the solid-liquid interface of the melt MS can also comprise variation values of other thermal field accessories in addition to the above described thermal field accessories, i.e., ΔH=Δh₁+Δh₂+Δh₃+ . . . .

In addition, it is to be noted that in the embodiments of the present disclosure, it is specified that a displacement of the solid-liquid interface of the melt MS moving vertically upward is a positive displacement, and a displacement of the ADC camera 2 moving to the right in a horizontal direction is a positive displacement; on the contrary, a displacement of the solid-liquid interface of the melt MS moving vertically downwards is a negative displacement, and a displacement of the ADC camera 2 moving to the left in the horizontal direction is a negative displacement.

Optionally, for the technical solutions shown in FIG. 3, in some examples, based on a geometric relationship between the height variation value and a horizontal displacement of the ADC camera, obtaining a horizontal displacement of the ADC camera according to the height variation value, comprises:

based on a geometric relationship between the height variation value and a first horizontal displacement of the ADC camera, obtaining a first correspondence relationship between the height variation value ΔH and the first horizontal displacement ΔX₁ of the ADC camera: ΔX₁=ΔH×tan θ; wherein θ represents an angle between a monitoring line of sight of the ADC camera and an outer wall of the monocrystalline silicon ingot in a vertical direction;

According to the first correspondence relationship and the height variation value ΔH, obtaining the first horizontal displacement ΔX₁ of the ADC camera.

It is to be understood that when a height position of the ADC camera 2 to the solid-liquid interface of the melt MS varies, in order to maintain the growth diameter of the monocrystalline silicon ingot monitored by the ADC camera 2 unvaried, it is necessary to adjust a horizontal position of the ADC camera 2 to ensure that the growth diameter of the monocrystalline silicon ingot monitored by the ADC camera 2 remains consistent. Based on this, FIG. 4 is a partial enlarged view of a black circular area in FIG. 2. As can be seen from the geometric relationships in FIG. 4, the first correspondence relationship between the first horizontal displacement ΔX₁ of the ADC camera 2 and the height variation value ΔH is: ΔX₁=ΔH×tan θ. Therefore, the influence of the height variation ΔH on the growth diameter of the monocrystalline silicon ingot can be adjusted by horizontally moving a horizontal displacement ΔX₁ of the ADC camera 2. At this point, the angle between the monitoring line of sight of the ADC camera 2 and the outer wall of the monocrystalline silicon ingot is the θ.

For the technical solutions shown in FIG. 3, in some examples, based on a geometric relationship between height variation value and horizontal displacement of the ADC camera, obtaining a horizontal displacement of the ADC camera according to the height variation value, comprises:
when the ADC camera pivoted by an angle 40 in the horizontal direction, based on a geometric relationship between the height variation value and a second horizontal displacement of the ADC camera, obtaining a second correspondence relationship between the height variation value ΔH and the second horizontal displacement ΔX₂ of the ADC camera: ΔX₂=ΔH×tan (θ+Δθ);
obtaining the second horizontal displacement of the ADC camera according to the second correspondence relationship and the height variation value.

It is to be noted that when the horizontal displacement ΔX₁ of the ADC camera 2 is over large, the monitoring line of sight of the ADC camera 2 is obstructed by an edge of the observation window 80 or the thermal shield 50. Therefore, in order to avoid such situation, horizontally moving the ADC camera by the displacement ΔX₁ cannot meet operation conditions of the ADC camera 2. On this basis, it is necessary to move the ADC camera 2 again to meet the monitoring requirements.

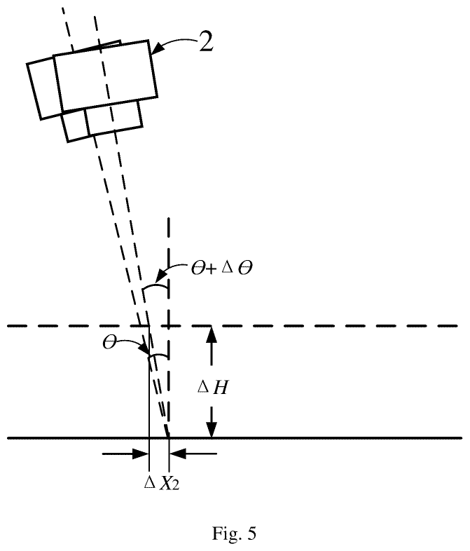

In order to avoid occurrence of the above situation, in the specific implementation process of the embodiments of the present disclosure, the second horizontal displacement of the ADC camera 2 can be determined by rotating the ADC camera 2 in the horizontal direction by an angle of Δθ. Firstly, as shown in FIG. 5, the ADC camera 2 pivoted by a certain angle Δθ in the horizontal direction. Then, based on the geometric relationship shown in FIG. 5 and ΔH, the second horizontal displacement of the ADC camera 2 can be calculated as ΔX₂=ΔH×tan (θ+Δθ). By the above method, the adjustment position of the ADC camera 2 can be accurately obtained, thereby avoiding impact on monitoring accuracy caused by repeated adjustments to the ADC camera 2 in the initial stage of the body process phase.

It is to be noted that there is a cross cursor at a center of a lens of the ADC camera 2, so it can be detected in advance when the monitoring line of sight of the ADC camera 2 is obstructed by moving the ADC camera 2 horizontally only by a horizontal displacement of ΔX₁. Therefore, adjusting the angle Δθ of the ADC camera 2 is only the work before the body process phase and may be completed together with the horizontal movement of the ADC camera 2, so there is no need to repeatedly adjust the ADC camera 2.

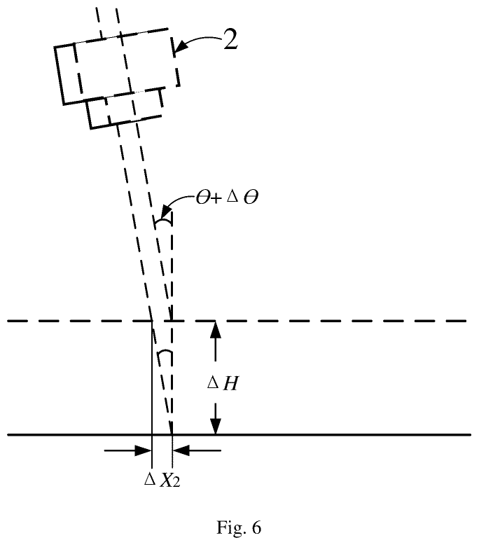

For the technical solutions shown in FIG. 3, in some examples, as shown in FIG. 6, the moving the ADC camera to a target position horizontally according to the horizontal displacement of the ADC camera, comprises:
moving the ADC camera to the target position horizontally according to the first horizontal displacement or the second horizontal displacement of the ADC camera.

Based on the same technical solution concept mentioned above, comparison results between calculated values and experimental values of the horizontal displacements of the ADC camera 2 are shown in Table 1.

TABLE 1

| ΔH (mm) | 57 | 17 | −27 |
|---|---|---|---|
| theoretical horizontal displacement (mm) | 17.64 | 5.36 | −8.35 |
| experimental horizontal displacement (mm) | 17.66 | 5.31 | −8.28 |
| tolerance (%) | 0.11 | 0.93 | 0.84 |

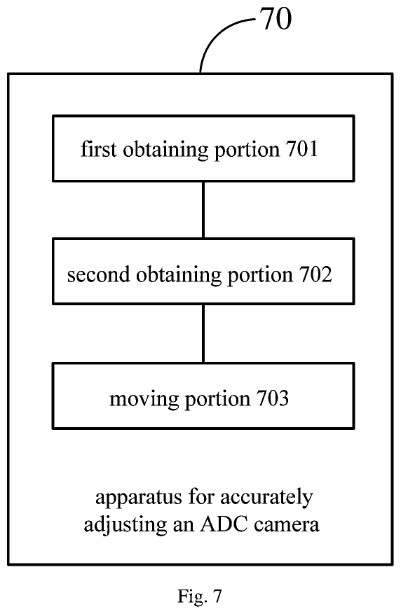

Based on the same invention concept as the above technical solutions, referring to FIG. 7, FIG. 7 shows an apparatus 70 for accurately adjusting an ADC camera provided in the embodiments of the present disclosure. The apparatus 70 comprises a first obtaining portion 701, a second obtaining portion 702 and a moving portion 703.

The first obtaining portion 701 is configured to, before pulling a monocrystalline silicon ingot, obtain a height variation value of an ADC camera from a solid-liquid interface of a melt, by separately comparing variations of thermal field accessories provided corresponding to the monocrystalline silicon ingot and a previous monocrystalline silicon ingot.

The second obtaining portion 702 is configured to, based on a geometric relationship between the height variation value and a horizontal displacement of the ADC camera, obtain a horizontal displacement of the ADC camera according to the height variation value; where the horizontal displacement is a first horizontal displacement or a second horizontal displacement.

The moving portion 703 is configured to move the ADC camera to a target position horizontally according on the horizontal displacement of the ADC camera.

In some examples, the first obtaining portion 701 is configured to:
obtain a height variation of a thermal insulation cover plate in the monocrystalline puller, a length variation of a thermal shield, and a melt gap variation of the melt when pulling the monocrystalline silicon ingot and the previous monocrystalline silicon ingot.

In some examples, the first obtaining portion 701 is configured to:
obtain a height variation value Δh₁ of the thermal insulation cover plate, a length variation value Δh₂ of the thermal shield and a melt gap variation value Δh₃ of the melt respectively, by comparing the variations of the thermal field accessories provided corresponding to the monocrystalline silicon ingot and the previous monocrystalline silicon ingot;
when pulling the current monocrystalline silicon ingot, according to the height variation value Δh₁ of the thermal insulation cover plate, the length variation value Δh₂ of the thermal shield and the melt gap variation value Δh₃ of the melt, obtain a height variation value ΔH=Δh₁+Δh₂+Δh₃ of the ADC camera from the solid-liquid interface of the melt.

In some examples, the second obtaining portion 702 is configured to:
based on a geometric relationship between the height variation value and a first horizontal displacement of the ADC camera, obtain a first correspondence relationship between the height variation value ΔH and the first horizontal displacement ΔX₁ of the ADC camera: ΔX₁=ΔH×tan θ; wherein θ represents an angle between the monitoring line of sight of the ADC camera and an outer wall of the monocrystalline silicon ingot in a vertical direction;
According to the first correspondence relationship and the height variation value ΔH, obtain the first horizontal displacement ΔX₁ of the ADC camera.

In some examples, the second obtaining portion 702 is configured to:
when the ADC camera pivoted by an angle 40 in the horizontal direction, based on a geometric relationship between the height variation value and a second horizontal displacement of the ADC camera, obtain a second correspondence relationship between the height variation value ΔH and the second horizontal displacement ΔX₂ of the ADC camera: ΔX₂=ΔH×tan (θ+Δθ);
obtain the second horizontal displacement of the ADC camera according to the second correspondence relationship and the height variation value.

In some examples, the moving portion 703 is configured to:
move the ADC camera to the target position horizontally according to the first horizontal displacement or the second horizontal displacement of the ADC camera.

It is to be understood that in this embodiment, “portion” may be a partial circuit, a partial processor, a partial program or software, etc., of course, it can also be a unit, a module, or a non-modular one.

In addition, in this embodiment, various components may be integrated into a single processing unit, each unit can physically exist separately, or two or more units can be integrated into one unit. The integrated units mentioned above can be implemented in a hardware functional module or a software functional module.

If the integrated units are realized in the form of software function modules and sold or used as independent products, they may be stored in a computer-readable storage medium. Based on this understanding, the essence of the technical solutions of the present disclosure or the part that contributes to the related art or the part of the technical solution may be embodied in the form of a software product. The computer software product is stored in a storage medium, comprises several instructions which enables a computer equipment (which may be a personal computer, a server, or a network equipment, etc.) or a processor to execute all or part of the steps of the methods described in various embodiments of the present disclosure. The storage medium comprises various media capable of storing program codes such as U disk, mobile hard disk, ROM, RAM, magnetic disk or optical disk.

Therefore, the embodiments of the present disclosure provide a computer storage medium, which comprises programs for accurately adjusting an ADC camera stored therein. The programs for accurately adjusting the ADC camera are executed by at least one processor to implement the method for accurately adjusting an ADC camera in above technical solutions.

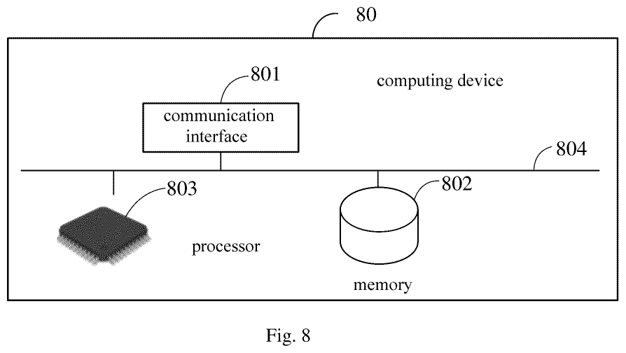

Based on the above apparatus 70 for accurately adjusting an ADC camera and the computer storage medium, referring to FIG. 8, FIG. 8 shows specific hardware structures of a computing equipment 80 that can implement the apparatus 70 for accurately adjusting an ADC camera provided in the embodiments of the present disclosure. The computing equipment 80 may be a wireless equipment, a mobile or cellular phone (comprising a smart phone), a personal digital assistant (PDA), a video game console (comprising a video monitor, a mobile video game equipment, a mobile video conference unit), a laptop, a desktop computer, a TV set-top box, a tablet computing equipment, an e-book reader, a fixed or mobile media player, etc. The computing equipment 80 comprises: a communication interface 801, a memory 802, and a processor 803. Various components are coupled together through a bus system 804. Understandably, the bus system 804 is used to achieve connection communication between these components. The bus system 804 comprises not only a data bus, but also a power bus, a control bus, and a status signal bus. However, for clarity, various buses are labeled as the bus system 804 in FIG. 8.

The communication interface 801 is used to receive and send signals during a process of receiving and sending information with other external network elements.

The memory 802 is used to store computer programs executed on the processor.

The processor 803 is used to perform the steps of the method for accurately adjusting an ADC camera in the above technical solutions when executing the computer programs.

It is to be understood that the memory 802 in the embodiments of the present disclosure may be volatile memory or non-volatile memory, or may comprise both volatile and non-volatile memories. Wherein the non-volatile memory may be a read-only memory (ROM), a programmable ROM (PROM), an erasable PROM (EPROM), an electrically EPROM (EEPROM), or flash memory. The volatile memory may be a random access memory (RAM), which serves as an external cache. By way of example but not limitation, many forms of RAM are available, such as static RAM (SRAM), dynamic RAM (DRAM), synchronous DRAM (SDRAM), double Data Rate SDRAM (DDRSDRAM), enhanced SDRAM (ESDRAM), Synchlink DRAM (SLDRAM), and direct rambus RAM (DRRAM). The memory 802 of the system and method described in the embodiments of the present disclosure aim to include but not limited to these and any other suitable types of memory.

The processor 803 may be an integrated circuit chip with signal processing capabilities. During the implementation process, each step of the above method can be completed through hardware integrated logic circuits or software instructions in the processor 803. The processor 803 mentioned above may be a general-purpose processor, a digital signal processor (DSP), an application specific integrated circuit (ASIC), a field programmable gate array (FPGA), or other programmable logic devices, discrete gate or transistor logic devices, or discrete hardware components, which can implement or execute the disclosed methods, steps and logical block diagrams in the embodiments of the present disclosure. The general-purpose processor may be a microprocessor or any conventional processor. The steps of the method disclosed in conjunction with the embodiments of the present disclosure can be directly implemented by a hardware decoding processor, or executed by a combination of hardware and software modules in the decoding processor. Software modules may be located in mature storage media in this field, such as random access memory, flash memory, read-only memory, programmable read-only memory, or electrically erasable programmable memory, registers, etc. The storage medium is provided in the memory 802, and the processor 803 reads information in the memory 802 and completes the steps of the above method in combination with its hardware.

It is to be understood that the embodiments described in the application may be implemented using hardware, software, firmware, middleware, microcode, or a combination thereof. For hardware implementation, processing units may be implemented in one or more application specific integrated circuits (ASICs), digital signal processing (DSP), DSP device (DSPD), programmable logic device (PLD), field-programmable gate array (FPGA), general-purpose processors, controllers, microcontrollers, microprocessors, other electronic units or combinations thereof which are configured to perform the functions described in the present application.

For software implementation, the techniques described in the application can be implemented through modules (such as procedures, functions, etc.) that perform the functions described in this application. Software codes can be stored in the memory and executed by the processor. The memory can be implemented within or outside the processor.

Specifically, the processor 803 is further configured to, when executing the computer program, perform the steps of the method for accurately adjusting an ADC camera described in the above technical solutions, which will not be further elaborated here.

According to the method, apparatus and equipment for accurately adjusting an ADC camera and the computer storage medium of the embodiments of the present disclosure, before pulling the monocrystalline silicon ingot, the height variation value of the ADC camera from the solid-liquid interface of a melt is obtained, by comparing variations of the thermal field accessories provided corresponding to the monocrystalline silicon ingot and the previous monocrystalline silicon ingot. On this basis, based on the geometric relationship between the height variation value and the horizontal displacement of the ADC camera, and according to the height variation value, the horizontal displacement of the ADC camera is obtained. Finally, the ADC camera is moved horizontally to the target position, so that a target position of the ADC camera can be accurately and timely determined after adjustments of the thermal field accessories, which enables growth of the monocrystalline silicon ingot to quickly and stably enter the body process phase from an initial stage of the body process phase, thereby improving quality of the monocrystalline silicon ingot in the initial stage of the body process phase.

It is to be noted that the technical solutions recorded in the embodiments of the present disclosure may be combined arbitrarily without conflicts.

The above is only specific implementation of the disclosure, but the protection scope of the present disclosure is not limited to this. Those of ordinary skill in the art may make various variations under the teaching of this application without departing from the spirit of this application and the protection scope of the claims, and such variations all fall within the protection scope of this application. Therefore, the protection scope of the present disclosure should be based on the protection scope of the claims mentioned.

1. A method for accurately adjusting an automatic diameter control (ADC) camera, comprising:
before pulling a monocrystalline silicon ingot, obtaining a height variation value of an ADC camera from a solid-liquid interface of a melt by separately comparing variations of thermal field accessories provided corresponding to the monocrystalline silicon ingot and a previous monocrystalline silicon ingot;
based on a geometric relationship between the height variation value and a horizontal displacement of the ADC camera, obtaining a horizontal displacement of the ADC camera according to the height variation value, wherein the horizontal displacement is a first horizontal displacement or a second horizontal displacement; and
moving the ADC camera horizontally to a target position according to the horizontal displacement of the ADC camera.

2. The method according to claim 1, wherein the variations of thermal field accessories provided corresponding to the monocrystalline silicon ingot and the previous monocrystalline silicon ingot include:
a height variation of a thermal insulation cover plate in a monocrystalline puller, a length variation of a thermal shield, and a melt gap variation of the melt between pulling the monocrystalline silicon ingot and the previous monocrystalline silicon ingot.

3. The method according to claim 2, wherein obtaining the height variation value of the ADC camera from the solid-liquid interface of the melt comprises:
obtaining a height variation value Δh₁ of the thermal insulation cover plate, a length variation value Δh₂ of the thermal shield and a melt gap variation value Δh₃ of the melt respectively, by comparing the variations of the thermal field accessories provided corresponding to the monocrystalline silicon ingot and the previous monocrystalline silicon ingot; and wherein
when pulling the monocrystalline silicon ingot, according to the height variation value Δh₁ of the thermal insulation cover plate, the length variation value Δh₂ of the thermal shield and the melt gap variation value Δh₃ of the melt, obtaining the height variation value ΔH=Δh₁+Δh₂+Δh₃ of the ADC camera from the solid-liquid interface of the melt.

4. The method according to claim 3, wherein obtaining the horizontal displacement of the ADC camera based on the height variation value comprises:
based on a geometric relationship between the height variation value and a first horizontal displacement of the ADC camera, obtaining a first correspondence relationship between the height variation value ΔH and the first horizontal displacement ΔX₁ of the ADC camera: ΔX₁=ΔH×tan θ, wherein θ represents an angle between a monitoring line of sight of the ADC camera and an outer wall of the monocrystalline silicon ingot in a vertical direction; and
according to the first correspondence relationship and the height variation value ΔH, obtaining the first horizontal displacement ΔX₁ of the ADC camera.

5. The method according to claim 3, wherein obtaining the horizontal displacement of the ADC camera according to the height variation value comprises:
when the ADC camera pivoted by an angle Δθ in a horizontal direction, based on a geometric relationship between the height variation value and the second horizontal displacement of the ADC camera, obtaining a second correspondence relationship between the height variation value ΔH and the second horizontal displacement ΔX₂ of the ADC camera: ΔX₂=ΔH×tan (θ+Δθ); and
obtaining the second horizontal displacement of the ADC camera according to the second correspondence relationship and the height variation value.

6. The method according to claim 4, wherein moving the ADC camera horizontally to the target position according to the horizontal displacement of the ADC camera comprises
moving the ADC camera to the target position horizontally according to the first horizontal displacement or the second horizontal displacement of the ADC camera.

7. An apparatus for accurately adjusting an ADC camera, comprising: a first obtaining portion, a second obtaining portion and a moving portion;
wherein the first obtaining portion is configured to, before pulling a monocrystalline silicon ingot, obtain a height variation value of an ADC camera from a solid-liquid interface of a melt, by separately comparing variations of thermal field accessories provided corresponding to the monocrystalline silicon ingot and a previous monocrystalline silicon ingot;
the second obtaining portion is configured to, based on a geometric relationship between the height variation value and a horizontal displacement of the ADC camera, obtain a horizontal displacement of the ADC camera according to the height variation value, wherein the horizontal displacement is a first horizontal displacement or a second horizontal displacement;
the moving portion is configured to move the ADC camera to a target position horizontally according to the horizontal displacement of the ADC camera.

8. Equipment for accurately adjusting an ADC camera, comprising: a communication interface, a memory and a processor, which are coupled together by a bus system;
wherein the communication interface is configured to receive and send signals during a process of receiving and sending information with other external network elements;
the memory is configured to store one or more computer programs executed on the processor;
the processor is configured to execute the one or more computer programs to perform;
before pulling a monocrystalline silicon ingot, obtaining a height variation value of an ADC camera from a solid-liquid interface of a melt by separately comparing variations of thermal field accessories provided corresponding to the monocrystalline silicon ingot and a previous monocrystalline silicon ingot;
based on a geometric relationship between the height variation value and a horizontal displacement of the ADC camera, obtaining a horizontal displacement of the ADC camera according to the height variation value, wherein the horizontal displacement is a first horizontal displacement or a second horizontal displacement; and
controlling to move the ADC camera to a target position horizontally according to the horizontal displacement of the ADC camera.

9. A computer storage medium, comprising a program for accurately adjusting an ADC camera stored therein; wherein the program for accurately adjusting the ADC camera is executed by at least one processor to implement the method according to claim 1.

10. A computer program product stored in a non-volatile storage medium, wherein the computer program product, when executed by at least one processor, implements the method according to claim 1.

11. The equipment according to claim 8, wherein the variations of thermal field accessories provided corresponding to the monocrystalline silicon ingot and a previous monocrystalline silicon ingot comprise:
a height variation of a thermal insulation cover plate in a monocrystalline puller, a length variation of a thermal shield, and a melt gap variation of the melt when pulling the monocrystalline silicon ingot and the previous monocrystalline silicon ingot.

12. The equipment according to claim 11, wherein before pulling a monocrystalline silicon ingot, when obtaining the height variation value of the ADC camera from the solid-liquid interface of the melt, the processor is configured to execute the one or more computer programs to perform:
obtaining a height variation value Δh₁ of the thermal insulation cover plate, a length variation value Δh₂ of the thermal shield and a melt gap variation value Δh₃ of the melt respectively, by comparing the variations of the thermal field accessories provided corresponding to the monocrystalline silicon ingot and the previous monocrystalline silicon ingot; and
when pulling the monocrystalline silicon ingot, according to the height variation value Δh₁ of the thermal insulation cover plate, the length variation value Δh₂ of the thermal shield and the melt gap variation value Δh₃ of the melt, obtaining the height variation value ΔH=Δh₁+Δh₂+Δh₃ of the ADC camera to the solid-liquid interface of the melt.

13. The equipment according to claim 12, wherein the processor is configured to execute the one or more computer program to obtain the horizontal displacement of the ADC camera based on the height variation value by:
based on a geometric relationship between the height variation value and a first horizontal displacement of the ADC camera, obtaining a first correspondence relationship between the height variation value ΔH and the first horizontal displacement ΔX₁ of the ADC camera: ΔX₁=ΔH×tan θ, wherein θ represents an angle between a monitoring line of sight of the ADC camera and an outer wall of the monocrystalline silicon ingot in a vertical direction; and
according to the first correspondence relationship and the height variation value ΔH, obtaining the first horizontal displacement ΔX₁ of the ADC camera.

14. The equipment according to claim 12, wherein, when the processor is further configured to execute the one or more computer programs to obtain the horizontal displacement of the ADC camera according to the height variation value by:
when the ADC camera pivoted by an angle 40 in a horizontal direction, based on a geometric relationship between the height variation value and the second horizontal displacement of the ADC camera, obtaining a second correspondence relationship between the height variation value ΔH and the second horizontal displacement ΔX₂ of the ADC camera: ΔX₂=ΔH×tan (θ+Δθ); and
obtaining the second horizontal displacement of the ADC camera according to the second correspondence relationship and the height variation value.

15. The equipment according to claim 13, wherein when moving the ADC camera horizontally to the target position according to the horizontal displacement of the ADC camera, the processor is further configured to execute the one or more computer programs to perform:
controlling to move the ADC camera to the target position horizontally according to the first horizontal displacement or the second horizontal displacement of the ADC camera.
